(19) United States
(12) Patent Application Publication
(10) Pub. No.: US 2025/0284193 A1
(43) Pub. Date: Sep. 11, 2025

(54) FILM FORMING APPARATUS, FILM FORMING METHOD, AND ARTICLE MANUFACTURING METHOD

(71) Applicant: CANON KABUSHIKI KAISHA, Tokyo (JP)

(72) Inventors: MASAKI SAITO, Tochigi (JP); HIROTOSHI TORII, Tochigi (JP)

(21) Appl. No.: 19/065,279

(22) Filed: Feb. 27, 2025

(30) Foreign Application Priority Data
Mar. 7, 2024 (JP) 2024-035235

(51) Int. Cl. G03F 7/00; H01L 21/02

(52) U.S. Cl. CPC G03F 7/0002; H01L 21/02118; H01L 21/02282; H01L 21/02348

(57) ABSTRACT

The present invention provides a film forming apparatus for forming a cured film of a composition on a substrate by performing a process of supplying the composition onto the substrate and curing the composition, comprising: a supplier configured to supply each of a plurality of kinds of compositions having different curing shrinkage rates onto the substrate; and a controller configured to control the process, wherein the substrate includes a plurality of regions with different average surface heights per unit area, and wherein the controller makes a ratio of the plurality of kinds of compositions supplied onto the substrate by the supplier in the process different among the plurality of regions so that a surface shape of the cured film formed on the substrate by performing the process is a target shape.

### BACKGROUND OF THE INVENTION

### Field of the Invention

The present invention relates to a film forming apparatus, a film forming method, and an article manufacturing method.

### Description of the Related Art

As the need for miniaturizing semiconductor devices increases, not only a conventional photolithography technique but also a microfabrication technique (film forming technique) for forming, on a substrate, a film controlled on a several nanometer order has received a great deal of attention. An example of such microfabrication technique is an imprint technique. In the imprint technique, it is possible to cure a composition in a state in which the uncured composition supplied onto a substrate is in contact with a mold, and separate the mold from the cured composition, thereby forming a cured film of the composition on the substrate.

In a manufacturing step of a semiconductor device, there is a need to form a planarized film (that is, a film having a flat surface) on a substrate including a step. As a general planarization technique for forming a planarized film on a substrate, there is known a technique for forming a coating film on a substrate using a coating apparatus such as a spin coater. However, in a method of forming a coating film on a substrate using a coating apparatus, it is difficult to planarize the coating film on the substrate on a nanoscale basis. Therefore, in recent years, there has been proposed a planarization technique for planarizing a composition on a substrate using a mold having a flat surface by applying the imprint technique (for example, Japanese Patent Laid-Open No. 2016-219679). In the planarization technique applied with the imprint technique, it is possible to cure a composition in a state in which the composition supplied onto a substrate is in contact with the flat surface of a mold, and separate the mold from the cured composition, thereby accurately planarizing the composition on the substrate. The mold used for the planarization technique is sometimes called a planar template or a superstrate.

A composition supplied onto a substrate in the planarization technique causes so-called curing shrinkage in which the volume of the composition decreases when the composition is cured. Therefore, if a substrate includes a plurality of regions with different average surface heights per unit area, it may become difficult to accurately form the cured film of the composition having a desired surface shape on the substrate due to curing shrinkage of the composition.

### SUMMARY OF THE INVENTION

The present invention provides, for example, a technique advantageous in accurately forming a cured film of a composition on a substrate.

According to one aspect of the present invention, there is provided a film forming apparatus for forming a cured film of a composition on a substrate by performing a process of supplying the composition onto the substrate and curing the composition, comprising: a supplier configured to supply each of a plurality of kinds of compositions having different curing shrinkage rates onto the substrate; and a controller configured to control the process, wherein the substrate includes a plurality of regions with different average surface heights per unit area, and wherein the controller makes a ratio of the plurality of kinds of compositions supplied onto the substrate by the supplier in the process different among the plurality of regions so that a surface shape of the cured film formed on the substrate by performing the process is a target shape.

Further features of the present invention will become apparent from the following description of exemplary embodiments with reference to the attached drawings.

### BRIEF DESCRIPTION OF THE DRAWINGS

FIG. 1 is a schematic view showing an example of the arrangement of a planarization apparatus according to an embodiment of the present invention;

FIG. 2 is a schematic view showing a supply step according to the embodiment of the present invention;

FIGS. 3A to 3F are schematic views showing a planarization process according to the embodiment of the present invention;

FIGS. 4A and 4B are views for explaining curing shrinkage of a composition in a baking step;

FIG. 5 is a flowchart illustrating the planarization process according to the embodiment of the present invention; and

FIGS. 6A to 6C are views for explaining an example of deciding the ratio of a plurality of kinds of compositions on a substrate.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate.

Furthermore, in the attached drawings, the same reference numerals are given to the same or similar configurations, and redundant description thereof is omitted.

In the specification and the accompanying drawings, directions will be indicated on an XYZ coordinate system in which directions parallel to the surface of a substrate (or a holding surface that holds a substrate) are defined as the X-Y plane, unless otherwise specified. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and an orientation is information that can be specified by values on the θX-, θY-, and θZ-axes.

A film forming apparatus is an apparatus that forms a cured film of a composition on a substrate by performing a process of supplying the composition onto the substrate and curing the composition. The film forming apparatus can be, for example, a shaping apparatus that performs a process (shaping process) of shaping a composition on a substrate using a mold. The shaping apparatus can cure a composition in a state in which a mold and the composition supplied onto a substrate are in contact with each other, and separate the mold from the cured composition, thereby forming the cured film of the composition on the substrate. Examples of the shaping apparatus are an imprint apparatus and a planarization apparatus. The imprint apparatus is an apparatus that brings a mold including a concave-convex pattern into contact with a composition (imprint material) on a substrate to form (transfer) the pattern on the composition. The shaping process performed by the imprint apparatus will sometimes be referred to as an imprint process hereinafter. The planarization apparatus is an apparatus that planarizes the surface of a composition by bringing a mold having a flat surface into contact with the composition on a substrate. The shaping process performed by the planarization apparatus will sometimes be referred to as a planarization process hereinafter.

The film forming apparatus may be an apparatus that forms a cured film of a composition on a substrate without using a mold. In this case, for example, the film forming apparatus can supply a composition onto a substrate, and then cure a liquid film formed after the composition spreads on the substrate, thereby forming the cured film of the composition on the substrate.

As the composition supplied onto the substrate, a curable composition (to be also referred to as a resin in an uncured state) to be cured by receiving curing energy is used. As the curing energy, an electromagnetic wave, heat, or the like can be used. The electromagnetic wave includes, for example, light selected from the wavelength range of 10 nm (inclusive) to 1 mm (inclusive), more specifically, infrared rays, visible light, or ultraviolet light. The curable composition can be a composition cured by light irradiation or heating. Among these, a photo-curable composition cured by light irradiation contains at least a polymerizable compound and a photopolymerization initiator, and may further contain a nonpolymerizable compound or a solvating medium (solvent), as needed. The nonpolymerizable compound is at least one material selected from the group consisting of a sensitizer, a hydrogen donor, an internal mold release agent, a surfactant, an antioxidant, and a polymer component. The composition can be arranged on the substrate in the form of a film by a spin coater or a slit coater. Alternatively, the composition may be arranged, by a liquid injection head, on the substrate in the form of droplets or in the form of an island or film formed by connecting a plurality of droplets. The viscosity (the viscosity at 25° C.) of the imprint material can be, for example, from 1 mPa's (inclusive) to 100 mPa's (inclusive).

A film forming apparatus according to an embodiment of the present invention will be described below. In this embodiment, a planarization apparatus will be exemplified as a film forming apparatus but the arrangements/processes of the planarization apparatus can be applied to another film forming apparatus such as an imprint apparatus.

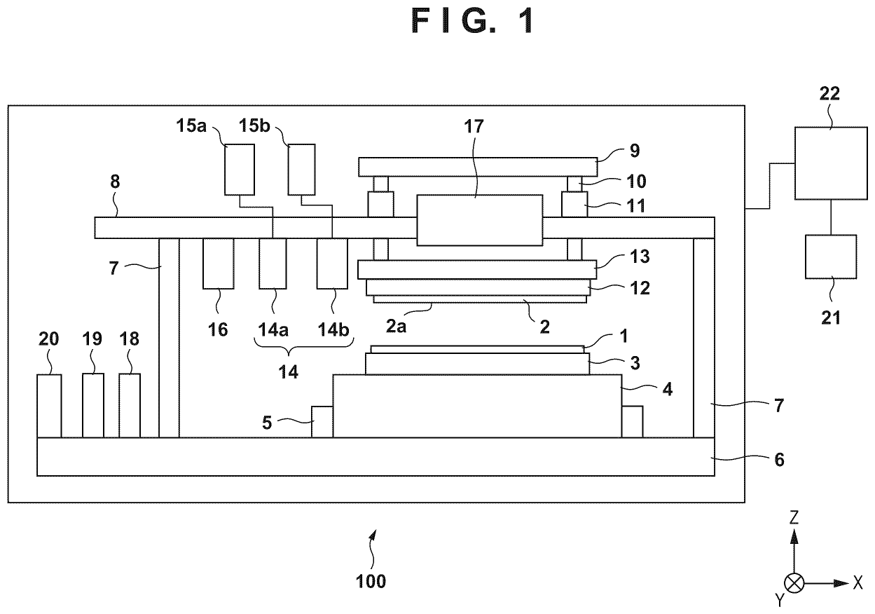

FIG. 1 is a schematic view showing an example of the arrangement of a planarization apparatus 100 according to this embodiment. The planarization apparatus 100 is one of lithography apparatuses used in a manufacturing step of a semiconductor device or a magnetic storage medium, and shapes a composition on a substrate 1 using a mold 2. More specifically, the planarization apparatus 100 cures the composition in a state in which the mold 2 and the composition on the substrate 1 are in contact with each other, and separates the mold 2 from the cured composition, thereby forming, on the substrate 1, a cured film (planarized film) of the composition with the surface planarized.

As the material of the substrate 1, for example, glass, a ceramic, a metal, a semiconductor, a resin, or the like is used. A member made of a material different from the substrate 1 may be provided on the surface of the substrate 1, as needed. The substrate 1 includes, for example, a silicon wafer, a compound semiconductor wafer, or silica glass. The substrate 1 has an uneven structure (concave-convex structure) caused by a pattern formed in the previous step, and the planarization apparatus 100 can be used to form, on the substrate 1, the planarized film to cover the uneven structure.

The mold 2 used by the planarization apparatus 100 includes a flat surface 2a as a contact surface (shaping surface) which is brought into contact with the composition on the substrate 1 to shape the composition, and is sometimes called a superstrate or a planar template. The mold 2 including the flat surface 2a can be defined such that 90% or more (preferably, 95% or more) of the contact surface that contacts the composition on the substrate 1 is flat.

As shown in FIG. 1, the planarization apparatus 100 can include a substrate chuck 3, a substrate stage 4, a substrate driver 5, a base plate 6, columns 7, a top plate 8, a guide bar plate 9, a guide bar 10, a mold driver 11, a mold chuck 12, and a mold head 13. Furthermore, the planarization apparatus 100 can include a supplier 14, a detector 16, a curing unit 17, a mold conveyance unit 18, a substrate conveyance unit 19, a baking unit 20, an input unit 21, and a controller 22. In this embodiment, the substrate chuck 3 and the substrate stage 4 form a substrate holder that holds the substrate 1, and the mold chuck 12 and the mold head 13 form a mold holder that holds the mold 2. In this example, the XYZ coordinate system is defined such that the horizontal plane is the XY plane and the vertical direction is the Z direction.

The substrate 1 is loaded from the outside into the planarization apparatus 100 by the substrate conveyance unit 19 including a conveyance hand, and is held by the substrate chuck 3. The substrate stage 4 is configured to support the substrate chuck 3 and move on the base plate 6 in the X and Y directions to position, at a predetermined position, the substrate 1 held by the substrate chuck 3. The substrate driver 5 includes, for example, a linear motor and an air cylinder, and drives the substrate 1 in the X and Y directions by driving (moving) the substrate stage 4 in the X and Y directions. The substrate driver 5 is not limited to the X and Y directions, and may have a function of driving the substrate stage 4 (substrate 1) in two or more axis directions (for example, six axis directions of the X direction, the Y direction, the Z direction, the θX direction, the θY direction, and the θZ direction). For example, the substrate driver 5 may have a rotation function of rotating the substrate 1 in the θZ direction by driving and rotating the substrate chuck 3 or the substrate stage 4 in the θZ direction.

The mold 2 is loaded from the outside into the planarization apparatus 100 by the mold conveyance unit 18 including a conveyance hand, and is held by the mold chuck 12. The mold 2 has, for example, a circular or rectangular outer shape, and includes the flat surface 2a conforming to the surface shape of the substrate 1 by contacting the composition on the substrate 1. In this embodiment, the flat surface 2a has a size equal to or larger than that of the substrate 1. The mold chuck 12 is supported by the mold head 13. The mold head 13 has a function of correcting the tilt of the mold 2 in the θX direction and the θY direction by driving the mold chuck 12. Each of the mold chuck 12 and the mold head 13 includes an opening (not shown) that passes light (ultraviolet light) emitted from the curing unit 17.

The columns 7 that support the top plate 8 are arranged on the base plate 6. The guide bar 10 extends through the top plate 8, and has one end fixed to the guide bar plate 9 and the other end fixed to the mold head 13. The mold driver 11 drives the mold head 13 via the guide bar 10 in the Z direction so as to bring the mold 2 held by the mold chuck 12 into contact with the composition on the substrate 1 or separate the mold 2 from the cured composition. The top plate 8 may be arranged with, for example, a height measurement system (not shown) for measuring the height (flatness) of the substrate 1 held by the substrate chuck 3 by an obliquely incident image shift method or the like.

This embodiment will describe an example of bringing the mold 2 into contact with the composition on the substrate 1 and separating the mold 2 from the composition on the substrate 1 by driving the mold 2 in the Z direction by the mold driver 11 but the present invention is not limited to this. For example, the contact step and the separation step may be performed by driving the substrate 1 in the Z direction by the substrate driver 5 or by relatively driving the mold 2 and the substrate 1 in the Z direction by the mold driver 11 and the substrate driver 5. That is, the mold driver 11 and the substrate driver 5 can form a driving mechanism for relatively driving the mold 2 and the substrate 1.

The supplier 14 supplies each of a plurality of kinds of compositions having different curing shrinkage rates onto the substrate 1. The supplier 14 of this embodiment can include a first discharge head 14a (first dispenser) that discharge a first composition reserved in a first tank 15a, and a second discharge head 14b (second dispenser) that discharges a second composition reserved in a second tank 15b. Each of the discharge heads 14a and 14b can employ, for example, a piezoelectric jet method, a micro solenoid method, or the like to discharge, as a droplet, the composition having a minute volume of about 1 pL (picoliter). The number of discharge holes in each of the discharge heads 14a and 14b is not limited and may be one (single nozzle) or exceed 100 (that is, a linear nozzle array or a combination of a plurality of linear nozzle arrays may be used).

The first composition and the second composition are different in curing shrinkage rate. The curing shrinkage rate indicates a ratio at which the volume of the composition decreases at the time of curing by receiving energy such as light or heat (that is, the ratio of the volume after curing to the volume before curing). In this embodiment, as the first composition discharged from the first discharge head 14a, for example, a composition having a relatively low curing shrinkage rate (a curing shrinkage rate lower than that of the second composition) of, for example, 0.95× is used. As the second composition discharged from the second discharge head 14b, a composition having a relatively high curing shrinkage rate (a curing shrinkage rate higher than that of the first composition) of, for example, 0.8× is used.

The detector 16 includes an off-axis (OA) scope, and is supported by the top plate 8. The detector 16 is used for a global alignment process of detecting an alignment mark provided in each of a plurality of shot regions on the substrate 1 and deciding the position of each shot region. By performing the global alignment process using the detector 16, it is possible to obtain the positional relationship between the supplier 14 (each of the discharge heads 14a and 14b) and the pattern formed on the substrate 1 in the previous lithography step or the like.

The curing unit 17 cures the composition by applying first energy to the composition on the substrate 1 via the mold 2. The curing unit 17 applies the first energy to the composition in a state in which the mold 2 and the composition on the substrate 1 are in contact with each other. In this embodiment, the first energy is light (for example, ultraviolet light). In this case, the curing unit 17 cures the composition by including a light source and irradiating the composition with light in a state in which the mold 2 and the composition on the substrate 1 are in contact with each other. Note that the first energy may be, for example, energy other than light, such as heat.

The baking unit 20 (heating unit) further cures the composition by applying second energy to the composition on the substrate 1, which has been cured by the curing unit 17 and separated from the mold 2. In this embodiment, the second energy is heat. In this case, the baking unit 20 further cures the composition by including a substrate holder that holds the substrate 1 and a heat radiation source such as a heater and performing, at a high temperature of, for example, 400° C. or the like, a heating process for the composition on the substrate 1 cured by the curing unit 17. By performing the heating process at a high temperature, a photopolymerization initiator and a solvating medium remaining in the composition on the substrate 1 are decomposed and the polymerization reaction of unpolymerized monomers is caused, thereby completing the curing reaction of the composition on the substrate 1. Note that as the substrate holder of the baking unit 20, the substrate holder formed from the substrate chuck 3 and the substrate stage 4 may be used.

The controller 22 can be formed by a computer (information processing apparatus) including a processor such as a Central Processing Unit (CPU) and a storage unit such as a memory. The controller 22 controls the planarization process by comprehensively controlling the respective units of the planarization apparatus 100 based on input information from the input unit 21 serving as a user interface and the like. The controller 22 may be formed by, for example, a PLD (an abbreviation of Programmable Logic Device) such as an FPGA (an abbreviation of Field Programmable Gate Array), an ASIC (an abbreviation of Application Specific Integrated Circuit), a general-purpose computer installed with a program, or a combination of all or some of them.

The planarization process is a series of processes of forming a planarized film on the substrate 1, and can include a supply step, a contact step, a curing step, a separation step, and a heating step. The supply step is a step of supplying the composition onto the substrate 1 by the supplier 14 (each of the discharge heads 14a and 14b). The contact step is a step of bringing the mold 2 and the composition on the substrate 1 into contact with each other by relatively driving the mold 2 and the substrate 1 in the Z direction to decrease the interval between the mold 2 and the substrate 1. The curing step is a step (first curing step) of curing the composition by the curing unit 17 in the state in which the mold 2 and the composition on the substrate 1 are in contact with each other. The separation step is a step of separating the mold 2 from the composition cured in the curing step by relatively driving the mold 2 and the substrate 1 in the Z direction to increase the interval between the mold 2 and the substrate 1. The baking step is a step (second curing step) of further curing the composition by performing the heating process of the composition on the substrate 1 by the baking unit 20 after the separation step. The planarization process may further include conveyance of the mold 2 to the mold chuck 12 by the mold conveyance unit 18, conveyance of the substrate 1 to the substrate chuck 3 by the substrate conveyance unit 19, and the global alignment process by the detector 16.

In the planarization process, if the substrate 1 includes a plurality of regions having different average surface heights per unit area, it may become difficult to accurately form, on the substrate, a cured film (planarized film) having a desired surface shape due to curing shrinkage of the composition in the curing step and the baking step. Therefore, in the planarization apparatus 100 of this embodiment, the supplier 14 includes the first discharge head 14a that discharges the first composition and the second discharge head 14b that discharges the second composition, and is configured to supply the plurality of kinds of compositions having different curing shrinkage rates onto the substrate 1. Then, the controller 22 makes the ratio of the plurality of kinds of compositions supplied onto the substrate 1 by the supplier 14 different among the plurality of regions having different average surface heights per unit area so that the surface shape of the cured film (planarized film) formed on the substrate by performing the planarization process becomes a target shape. That is, the controller 22 makes the ratio different among the plurality of regions so that the difference in surface height of the cured film (planarized film) formed on the substrate by performing the planarization process between the plurality of regions falls within an allowable range. The average surface height per unit area is defined as an averaged value of the surface height of the substrate 1 per unit area, and will sometimes simply be referred to as an “average surface height” hereinafter.

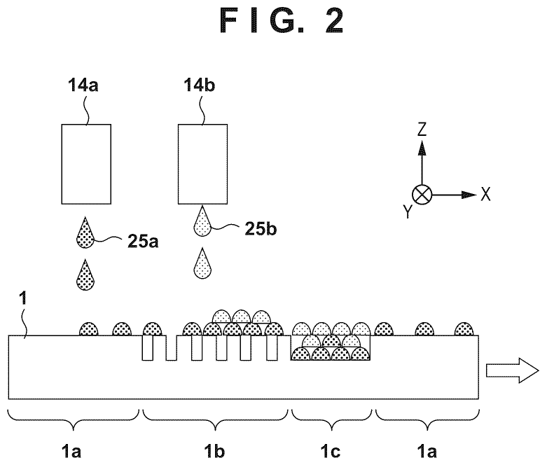

An example of a planarization method (film forming method) according to this embodiment will be described in detail next. FIG. 2 is a schematic view showing the supply step of supplying the plurality of kinds of compositions onto the substrate 1 by the discharge heads 14a and 14b according to this embodiment. The substrate 1 including three kinds of regions 1a to 1c having different average surface heights will be exemplified below. The region 1a is a region where no concave-convex pattern is formed. The region 1b is a region where a concave-convex pattern is formed. The region 1c is a region where a concave portion (to be sometimes referred to as a bathtub portion hereinafter) having a width larger than that of the concave portion of the concave-convex pattern in the region 1b is formed.

As shown in FIG. 2, the controller 22 causes the supplier 14 to discharge a plurality of kinds of compositions 25a and 25b while relatively moving the substrate 1 and the supplier 14 (the discharge heads 14a and 14b) in one direction. More specifically, the substrate 1 on the substrate stage 4 is scanned and driven under the discharge heads 14a and 14b when the substrate driver 5 drives the substrate stage 4. The first discharge head 14a discharges the first composition 25a as a plurality of droplets. The second discharge head 14b discharges, as a plurality of droplets, the second composition 25b whose curing shrinkage rate is different from that of the first composition 25a. The controller 22 appropriately controls the discharge amounts and discharge timings of the compositions 25a and 25b from the discharge heads 14a and 14b based on the relative position information between the substrate 1 and the substrate stage 4, the position information of the substrate stage 4, and supply pattern information. This can supply the plurality of kinds of compositions 25a and 25b at desired positions on the substrate 1. Note that the plurality of kinds of compositions 25a and 25b may sometimes collectively be referred to as the “composition 25” hereinafter.

The relative position information can be obtained by measuring the relative position (coordinates) between the pattern on the substrate 1 and the substrate stage 4 using the detector 16. The supply pattern information may be understood as information representing the distribution of the composition on the substrate 1 arranged as droplets, and can be generated (calculated) in advance so that the surface shape of the planarized film (cured film) formed on the substrate 1 by performing the planarization process becomes the target shape. The target shape is a flat shape in the planarization apparatus 100 (planarization process).

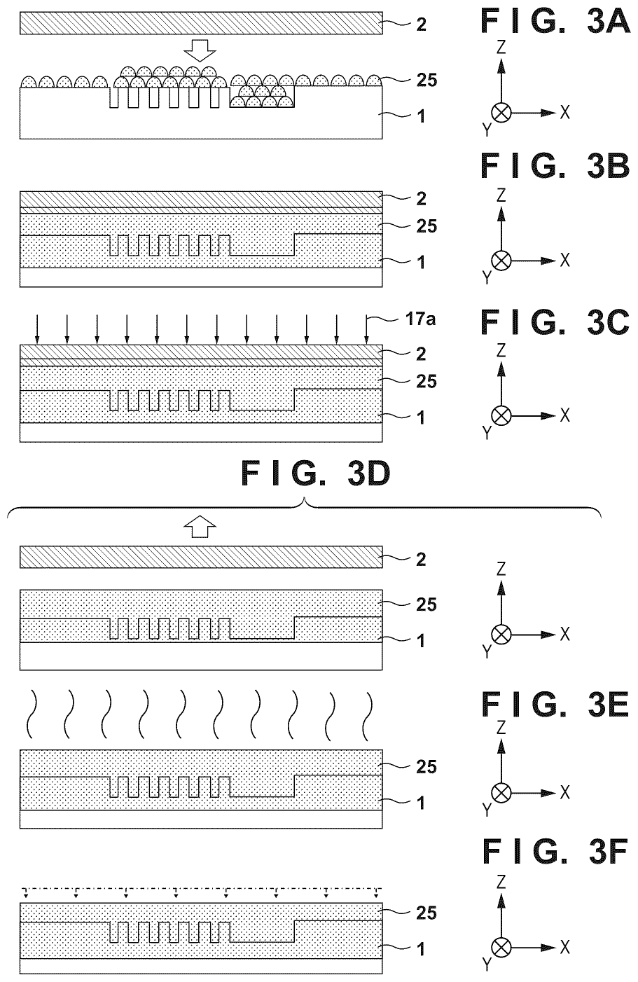

FIGS. 3A to 3F are schematic views showing the planarization process according to this embodiment. FIGS. 3A to 3F show steps performed after the supply step. After the supply step, as shown in FIG. 3A, the mold driver 11 drives the mold 2 in the −Z direction to bring the mold 2 into contact with the liquid composition 25 supplied on the substrate 1 (contact step). This forms the layer (liquid film) of the liquid composition 25 between the substrate 1 and the mold 2, as shown in FIG. 3B. After that, as shown in FIG. 3C, the curing unit 17 cures the composition 25 by irradiating the composition 25 on the substrate 1 with light 17a (ultraviolet light) via the mold 2 (curing step). In this curing step, curing shrinkage of the composition 25 may occur.

After the curing step, as shown in FIG. 3D, the mold driver 11 drives the mold 2 in the +Z direction to separate the mold 2 from the cured composition 25 on the substrate 1 (separation step). After the separation step, the substrate 1 is conveyed to the baking unit 20 by driving of the substrate stage 4 or by the substrate conveyance unit 19. In the baking unit 20, the substrate 1 and the composition 25 on the substrate 1 undergo, for example, a heating process at a high temperature of 400° C. (baking step), as shown in FIG. 3E. In the baking step as well, similar to the curing step, curing shrinkage of the composition 25 may occur, as shown in FIG. 3F. By performing these steps, the planarized film is formed on the substrate 1.

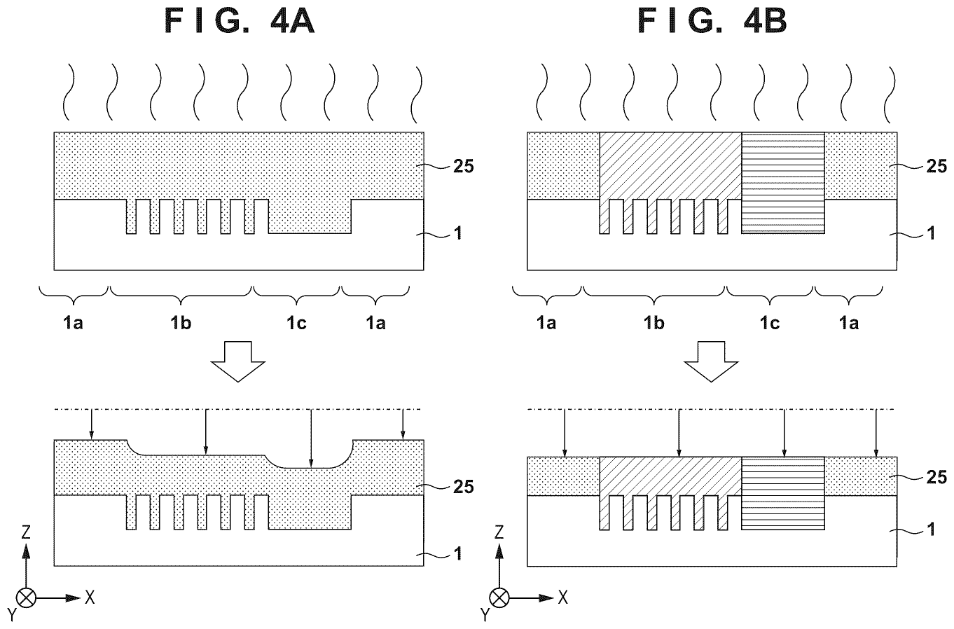

Curing shrinkage of the composition 25 in the baking step will be described next with reference to FIGS. 4A and 4B. In the planarization process, curing shrinkage of the composition 25 on the substrate 1 occurs not only in the curing step by light irradiation but also in the baking step of performing the heating process. In the baking step, by heating the composition 25 on the substrate 1 at a high temperature, progression of the polymerization reaction of the composition 25 that did not react in the curing step by light irradiation, a solvating medium decomposition/volatilization reaction, a polymerization initiator decomposition reaction, and the like occur in a superimposed manner, thereby causing curing shrinkage of the composition 25. The curing shrinkage rate changes depending on the kind of a monomer material, the degree of progress of the photopolymerization reaction, the composition ratio between the solvating medium and the photopolymerization initiator, and the like. However, in general, a shrinkage amount of 0.95× (a shrinkage rate of 5%) or less is obtained by a volume ratio to the volume before baking.

FIG. 4A is a schematic view showing the state of the curing shrinkage of the composition 25 in a case where a film is formed by a single kind of composition 25 on the substrate 1 including the regions 1a to 1c. In the region 1b including the concave-convex pattern and the region 1c including the bathtub portion, the film thickness of the composition 25 is large, as compared to the region 1a where neither a concave-convex pattern nor a bathtub portion is formed, and thus the curing shrinkage amount of the composition 25 is large. As a result, the flatness of the cured film (planarized film) of the composition 25 formed on the substrate 1 after the baking step may decrease.

On the other hand, FIG. 4B is a schematic view showing the state of the curing shrinkage of the composition 25 in a case where the curing shrinkage rate of the composition 25 in each of the regions 1a to 1c is appropriately adjusted. In the example shown in FIG. 4B, the ratio of the plurality of kinds of compositions 25 is made different among the plurality of regions 1a to 1c in accordance with the average surface height (average depth) so that the curing shrinkage amount of the composition 25 is constant over the entire region of the substrate 1. By appropriately adjusting the curing shrinkage rate of the composition 25 in accordance with the average surface height, the curing shrinkage amount is made constant over the entire region of the substrate 1, thereby making it possible to improve the flatness of the cured film (planarized film) of the composition 25 formed on the substrate 1 after the baking step.

In the curing shrinkage of the composition 25 in the region 1b where the relatively fine concave-convex pattern of 10 nm (inclusive) to 2,000 nm (inclusive) is formed, the shape of the concave-convex pattern is not directly reflected on the upper surface of the composition 25 due to the internal flow of the composition 25 and the like. That is, curing shrinkage according to the average surface height (average depth) of the concave-convex pattern occurs in the composition 25 on the region 1b including the concave-convex pattern. Therefore, in this embodiment, the regions 1a to 1c in each of which the ratio of the plurality of kinds of compositions 25a and 25b is changed in accordance with the average surface height are set.

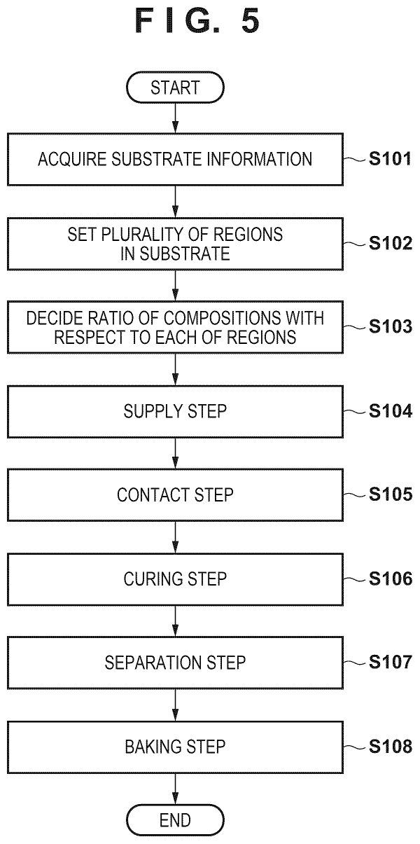

FIG. 5 is a flowchart illustrating the planarization process according to this embodiment. Each step of the flowchart shown in FIG. 5 can be controlled by the controller 22.

In step S101, the controller 22 acquires information (to be sometimes referred to as substrate information hereinafter) representing the surface shape of the substrate 1 to undergo the planarization process. The substrate information is information representing the coordinates and/or depths (surface heights) of the concave-convex pattern and the bathtub portion on the substrate 1. For example, the controller 22 can acquire the substrate information based on the information input via the input unit 21. The controller 22 can also acquire the substrate information based on a result of actually measuring the concave-convex pattern and the bathtub portion formed on the substrate 1 or based on mask design information (CAD data) in the previously performed lithography step and information in an etching step.

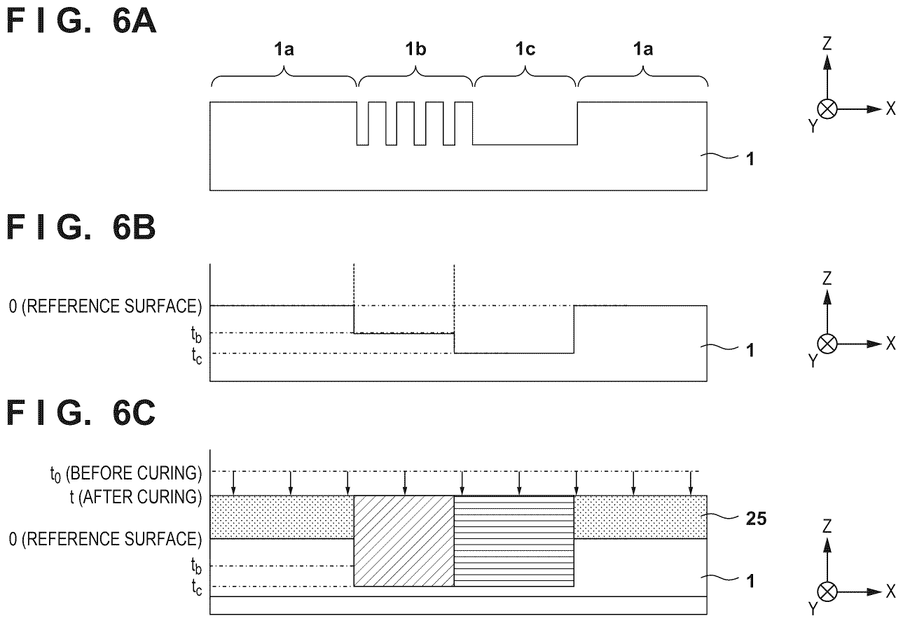

In step S102, the controller 22 calculates the average surface height based on the substrate information acquired in step S101, and sets, on the substrate 1, based on the average surface height, a plurality of regions among which the ratio of the plurality of kinds of compositions 25 is made different. FIGS. 6A and 6B are views for explaining an example of a method of setting a plurality of regions on the substrate 1 based on the average surface height. Assume that the concave-convex pattern and the bathtub portion are formed on the substrate 1, as shown in FIG. 6A. Then, the controller 22 calculates the average surface height per unit area, as shown in FIG. 6B. More specifically, when the average surface height of a portion where neither the concave-convex pattern nor the bathtub portion exists is set to “0 (reference surface)”, the average surface height of a portion where the concave-convex pattern is formed is calculated as “t_{b}” and the average surface height of a portion where the bathtub portion is formed is calculated as “t_{c}”. Then, the controller 22 can set, on the substrate 1, the region 1a (most projected region) whose average surface height is the height of the reference surface, the region 1b whose average surface height is “t_{b}”, and the region 1c (most recessed region) whose average surface height is “t_{c}”.

In step S103, the controller 22 determines (calculates) the ratio of the plurality of kinds of compositions 25 supplied to each of the regions 1a to 1c on the substrate 1. An example of using, as the plurality of kinds of compositions 25, the first composition 25a discharged from the first discharge head 14a and the second composition 25b discharged from the second discharge head 14b will now be described. In this case, the ratio of the plurality of kinds of compositions 25 indicates the ratio of the first composition 25a and the second composition 25b. With respect to the ratio, the ratio of one of the plurality of kinds of compositions 25 may be 100%. For example, with respect to the ratio, the ratio of the first composition 25a to the second composition 25b can be 100% to 0% or the ratio of the first composition 25a to the second composition 25b can be 0% to 100%.

FIG. 6C is a view for explaining each definition in an example of the method of deciding the ratio of the plurality of kinds of compositions 25. In deciding the ratio of the plurality of kinds of compositions 25, the height of the reference surface of the substrate 1 is represented by “0”, and the target surface height of the planarized film (that is, the planarized film after curing) to be formed on the substrate 1 by the planarization process is represented by “t”. The target surface height t is a process parameter determined in a step performed after the planarization process, and is generally, preferably 25 nm to 200 nm. The volume ratio before and after curing of the first composition 25a (that is, the ratio of the volume after curing to the volume before curing) is represented by “s₁”, and the volume ratio of the first composition 25a to the total volume of the plurality of kinds of compositions 25a and 25b supplied to each of the regions 1a to 1c is represented by “p₁”. Similarly, the volume ratio before and after curing of the second composition 25b (that is, the ratio of the volume after curing to the volume before curing) is represented by “s₂”, and the volume ratio of the second composition 25b to the total volume of the plurality of kinds of compositions 25a and 25b supplied to each of the regions 1a to 1c is represented by “p₂”. In this case, assume that s₁>s₂. Furthermore, the surface height of the composition 25 (liquid film) before curing is defined as “t₀”. In this embodiment, to minimize the curing shrinkage amount of the composition, only the first composition 25a is supplied to the region 1c as the most recessed region, and the ratio and the supply amounts of the first composition 25a and the second composition 25b are adjusted in each of the regions 1b and 1c other than the region 1c.

With respect to the region 1a as the most projected region, simultaneous equations relating to the surface height t₀ of the composition 25 before curing, the volume ratio p₁ of the first composition 25a, and the volume ratio p₂ of the second composition 25b are derived as follows. Note that in the following simultaneous equations, the volume ratio p₁ of the first composition 25a in the region 1a is represented by “p₁ₐ”, and the volume ratio p₂ of the second composition 25b in the region 1a is represented by “p₂ₐ”.

$$\{ \begin{matrix}t = ( {s}_{1} {p}_{1 a} + {s}_{2} {p}_{2 a} ) {t}_{0} \\ t + {t}_{c} = {s}_{1} ( {t}_{0} + {t}_{c} ) \\ {p}_{1 a} + {p}_{2 a} = 1\end{matrix}$$

By solving the above simultaneous equations, with respect to the region 1a on the substrate 1, it is possible to obtain the surface height t₀ of the composition 25 before curing, the volume ratio p₁ₐ of the first composition 25a, and the volume ratio p₂ₐ of the second composition 25b for implementing the target surface height t after curing.

$${t}_{0} = \frac{t + ( 1 - {s}_{1} ) {t}_{c}}{{s}_{1}} , \\ {p}_{1 a} = \frac{( {s}_{1} - {s}_{2} ) t - {s}_{2} ( 1 - {s}_{1} ) {t}_{c}}{( {s}_{1} - {s}_{2} ) ( t + ( 1 - {s}_{1} ) {t}_{c} )} , \\ {p}_{2 a} = \frac{{s}_{1} ( 1 - {s}_{1} ) {t}_{c}}{( {s}_{1} - {s}_{2} ) ( t + ( 1 - {s}_{1} ) {t}_{c} )}$$

With respect to the region 1b existing between the most projected region and the most recessed region, simultaneous equations relating to the surface height t₀ of the composition 25 before curing, the volume ratio p₁ of the first composition 25a, and the volume ratio p₂ of the second composition 25b are derived as follows. Note that in the following simultaneous equations, the thickness of the composition 25 in the region 1b before curing is represented by “t_{0b}”. In addition, the volume ratio p₁ of the first composition 25a in the region 1b is represented by “p_{1b}”, and the volume ratio p₂ of the second composition 25b in the region 1b is represented by “p_{2b}”.

$$\{ \begin{matrix}{t}_{0 b} = {t}_{0} + {t}_{b} \\ {t}_{0} = \frac{t + ( 1 - {s}_{1} ) {t}_{c}}{{s}_{1}} \\ t + {t}_{b} = {t}_{0 b} ( {s}_{1} {p}_{1 b} + {s}_{2} {p}_{2 b} ) \\ {p}_{1 b} + {p}_{2 b} = 1\end{matrix}$$

By solving the above simultaneous equations, with respect to the region 1b on the substrate 1, it is possible to obtain the volume ratio p_{1b} of the first composition 25a and the volume ratio p_{2b} of the second composition 25b for implementing the target surface height t after curing.

$${t}_{0 b} = {t}_{b} + \frac{t + ( 1 - {s}_{1} ) {t}_{c}}{{s}_{1}} , \\ {p}_{1 b} = \frac{( {s}_{1} - {s}_{2} ) t + {s}_{1} ( 1 - {s}_{2} ) {t}_{b} - {s}_{2} ( 1 - {s}_{1} ) {t}_{c}}{( {s}_{1} - {s}_{2} ) ( t + {s}_{1} {t}_{b} + ( 1 - {s}_{1} ) {t}_{c} )} , \\ {p}_{2 b} = \frac{{s}_{1} ( 1 - {s}_{1} ) ( - {t}_{b} + {t}_{c} )}{( {s}_{1} - {s}_{2} ) ( t + {s}_{1} {t}_{b} + ( 1 - {s}_{1} ) {t}_{c} )}$$

In this way, it is possible to calculate the ratio of the plurality of kinds of compositions 25a and 25b applied to each of the regions 1a to 1c to obtain a flat surface on the surface of the composition after curing. An example of calculation will be explained. Assume that t=50 nm, s₁=0.95, s₂=0.8, the average surface height t_{b} of the region 1b on the substrate 1 is set to 50 nm, and the average surface height t_{c} of the region 1c is set to 100 nm. By substituting the parameter values in the above simultaneous equations, t₀=57.9 nm, p₁ₐ=0.42, p₂ₐ=0.58, p_{1b}=0.85, and p_{2b}=0.15 can be obtained.

In step S104, the controller 22 supplies the plurality of kinds of compositions 25a and 25b onto the substrate 1 by the supplier 14 based on the ratio of the plurality of compositions 25a and 25b determined with respect to each of the regions 1a to 1c in step S103 (supply step). In this embodiment, as described above, the supplier 14 includes the first discharge head 14a that discharges the first composition 25a, and the second discharge head 14b that discharges the second composition 25b. The controller 22 controls the discharge of the composition from each of the discharge heads 14a and 14b so that the first composition 25a and the second composition 25b are supplied to each of the regions 1a to 1c at the ratio determined in step S103 while relatively moving the substrate 1 and the supplier 14 in one direction.

In step S105, the controller 22 performs the contact step described above with reference to FIGS. 3A and 3B. In step S106, the controller 22 performs the curing step described above with reference to FIG. 3C. In step S107, the controller 22 performs the separation step described above with reference to FIG. 3D. Next, in step S108, the controller 22 performs the baking step described above with reference to FIG. 3E.

Next, an example of a correction method of a planarization error will be described. A planarization error can be defined as a film thickness error and/or a flatness error in the planarized film (cured film) formed on the substrate 1 by the planarization process. The film thickness error may be understood as a deviation from a target film thickness, and the flatness error may be understood as a deviation from target flatness.

In the actual planarization process, a planarization error unique to the apparatus may occur in the planarized film formed on the substrate 1 by the planarization process due to a factor such as volatilization of each of the compositions 25a and 25b, the flatness error of the substrate chuck 3, or the flatness error of the mold 2. Such planarization error can be corrected by, for example, the following method.

First, an example of a method of deciding (correcting) the ratio of the plurality of kinds of compositions 25a and 25b based on information representing the measurement result of a cured film formed by a past planarization process will be described. In this case, by the above-described calculation method or the like, the ratio (that is, the supply pattern) of the plurality of kinds of compositions 25a and 25b is determined with respect to each of the regions 1a to 1c on the substrate 1, and the compositions 25a and 25b are actually supplied onto the substrate 1 based on the ratio, thereby executing the planarization process. The film thickness distribution and/or the flatness of the planarized film (cured film) formed on the substrate 1 by the planarization process is measured. For example, an ellipsometer, an atomic force microscope (AFM), or the like can be used to measure the film thickness distribution and/or the flatness of the planarized film.

The controller 22 determines (calculates) again the ratio of the plurality of kinds of compositions 25a and 25b with respect to each of the regions 1a to 1c on the substrate 1 based on the measurement result of the film thickness distribution and/or the flatness of the planarized film. That is, the controller 22 determines (calculates) the ratio of the plurality of kinds of compositions 25a and 25b to be supplied onto the substrate by a subsequent planarization process based on the measurement result of the film thickness distribution and/or the flatness of the planarized film formed by the past planarization process.

For example, the target surface height (the height from the reference height) of the planarized film to be formed on the substrate by the planarization process is represented by “t”. The average surface height calculated from the substrate information with respect to a given region d on the substrate is represented by “ta”, and the surface height actually measured with respect to the planarized film formed on the region d by performing the planarization process is represented by “t”. In this case, the actual film thickness of the planarized film formed on the region d is “t′+t_{d}”, and the film thickness ratio to the target film thickness “t+t_{d}” is “(t′+t_{d})/(t+t_{d})”. This film thickness ratio indicates the film thickness error of the planarized film. The film thickness error can be corrected by only multiplying the supply amounts of the components 25a and 25b by “(t′+t_{d})/(t+t_{d})” as the reciprocal of the film thickness ratio without changing the ratio of the first composition 25a and the second composition 25b. As an example, if t=50 nm, t_{d}=100 nm, and t′=40 nm, the calculation result of the reciprocal “(t′+t_{d})/(t+t_{d})” of the film thickness ratio is represented by three significant digits, that is, “1.07”. That is, by setting the total amount of the first composition 25a and the second composition 25b to be supplied to the region d to an amount obtained by multiplying the supply amounts determined based on the substrate information by 1.15, the planarization error can be corrected.

In the above example, the planarization error is corrected by adjusting only the supply amounts of the compositions 25a and 25b without changing the ratio of the first composition 25a and the second composition 25b. However, the present invention is not limited to this, and it is also possible to correct the error of the planarized film finally formed on the substrate by adjusting the ratio of the first composition 25a and the second composition 25b without changing the supply amounts of the compositions 25a and 25b. In this case, in the above-described simultaneous equations for calculating the ratio of the first composition 25a and the second composition 25b, the planarization error “t−t′” can be added to the target surface height t of the planarized film, thereby obtaining the appropriate ratio. That is, “2t−t” is used as the target surface height of the planarized film.

Next, an example of a method of deciding (correcting) the ratio of the plurality of kinds of compositions 25a and 25b based on post-processing information will be described. The post-processing information can be information representing the characteristic of the lithography apparatus that forms the pattern on the substrate 1 after forming the planarized film (cured film) on the substrate 1 by performing the planarization process.

The substrate 1 on which the planarized film has been formed is generally coated with a resist on the upper surface of the planarized film, and is used as the reference surface in the lithography step. In the recent lithography step using extreme ultraviolet (EUV) light, the depth of focus allowed to form an image is decreasing year by year along with a decrease in wavelength of exposure light and an increase in NA of an exposure optical system. The lithography apparatus used in the lithography step has, as the characteristic of the apparatus, a focusing error (difference in image heights) unique to the apparatus, caused by an optical system error, a measurement system error, a flatness error of the substrate chuck, and the like. The focusing error (image plane height error) unique to the lithography apparatus is measured in advance, and the target surface height of the planarized film formed by the planarization process is adjusted in accordance with the focusing error of the lithography apparatus used in the post processing. This can reduce the influence of the focusing error unique to the lithography apparatus.

For example, the average surface height calculated from the substrate information with respect to a given region e on the substrate 1 is represented by “tₑ”, and the focusing error of the lithography apparatus in the post processing in the region is represented by “tₑ”. The focusing error tₑ′ has a positive value in a direction away from the surface of the substrate 1. The target surface height of the planarized film without considering the focusing error is “t” as defined above. If the above definition is used, the ideal film thickness of the planarized film in the region e in consideration of the focusing error is “t+tₑ”. When calculating the ratio of the first composition 25a and the second composition 25b to be supplied to the region e, the new target value “t+tₑ” is used instead of the target surface height t of the planarized film without considering the focusing error. This can determine the ratio of the first composition 25a and the second composition 25b, which can reduce the influence of the focusing error in the post processing.

Next, a preferred example of the arrangement (composition) of each of the compositions 25a and 25b used in this embodiment will be described. The substrate 1 on which the planarized film has been formed is generally processed by an etching step and a chemical machine polishing (CMP) step after resist coating and a lithography step. In the etching step and the chemical machine polishing (CMP) step, a variation in processing rate is not preferable since it causes a variation in pattern to be formed. To cope with this, the planarized film formed on the substrate 1 by performing the planarization process of this embodiment preferably has the chemically/mechanically uniform property regardless of the ratio of the plurality of kinds of compositions 25a and 25b.

The property can be implemented when each of the plurality of kinds of compositions 25a and 25b contains a monomer and a polymerization initiator (for example, a photopolymerization initiator), and the monomers are of the same kind and the composition ratios of the polymerization initiators are made different in the plurality of kinds of compositions 25a and 25b. Since the photopolymerization initiator is decomposed/volatilized by the photo-curing process in the curing step and the heating process in the baking step to cause curing shrinkage of the composition 25, it is possible to appropriately adjust the curing shrinkage rate while keeping the same chemical/mechanical property of the finally obtained planarized film. The property can also be implemented when each of the plurality of kinds of compositions 25a and 25b contains a monomer, a polymerization initiator, and a solvating medium (solvent), and the monomers and the polymerization initiators are of the same kinds and the composition ratios of the solvating media are made different in the plurality of kinds of compositions 25a and 25b.

As described above, in the planarization apparatus 100 according to this embodiment, the supplier 14 is configured to supply the plurality of kinds of compositions 25a and 25b having different curing shrinkage rates onto the substrate 1. Then, the controller 22 makes the ratio of the plurality of kinds of compositions 25a and 25b supplied onto the substrate 1 by the supplier 14 different among the plurality of regions having different average surface heights per unit area so that the surface shape of the planarized film formed on the substrate by performing the planarization process becomes a target shape. This can accurately form the planarized film (cured film) having the desired surface shape on the substrate. This embodiment has explained an example in which the controller 22 determines (calculates) the ratio of the plurality of kinds of compositions 25a and 25b, but the present invention is not limited to this and an external apparatus (information processing apparatus) of the planarization apparatus 100 may determine (calculate) the ratio. In this case, the planarization apparatus 100 can perform the supply step based on the ratio determined by the external apparatus.

### <Embodiment of Article Manufacturing Method>

The article manufacturing method according to the embodiment of the present invention is suitable for manufacturing an article, for example, a microdevice such as a semiconductor device or an element having a fine structure. The article manufacturing method according to this embodiment includes a forming step of forming a cured film of a composition on a substrate using the above-described film forming method, a processing step of processing the substrate having undergone the forming step, and a manufacturing method of manufacturing an article from the substrate having undergone the processing step. Furthermore, the manufacturing method includes other known steps (oxidation, deposition, vapor deposition, doping, planarization, etching, resist removal, dicing, bonding, packaging, and the like). The article manufacturing method according to this embodiment is advantageous in at least one of the performance, quality, productivity, and production cost of the article, as compared to conventional methods.

### OTHER EMBODIMENTS

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-035235 filed on Mar. 7, 2024, which is hereby incorporated by reference herein in its entirety.

What is claimed is:

1. A film forming apparatus for forming a cured film of a composition on a substrate by performing a process of supplying the composition onto the substrate and curing the composition, comprising:
a supplier configured to supply each of a plurality of kinds of compositions having different curing shrinkage rates onto the substrate; and
a controller configured to control the process,
wherein the substrate includes a plurality of regions with different average surface heights per unit area, and
wherein the controller makes a ratio of the plurality of kinds of compositions supplied onto the substrate by the supplier in the process different among the plurality of regions so that a surface shape of the cured film formed on the substrate by performing the process is a target shape.

2. The apparatus according to claim 1, wherein the controller determines the ratio with respect to each of the plurality of regions on the substrate based on information representing a surface shape of the substrate.

3. The apparatus according to claim 1, wherein the controller causes the supplier to discharge each of the plurality of kinds of compositions while relatively moving the supplier and the substrate in one direction.

4. The apparatus according to claim 1, wherein the supplier includes a first discharge head configured to discharge a first composition and a second discharge head configured to discharge a second composition whose curing shrinkage rate is different from that of the first composition.

5. The apparatus according to claim 1, wherein
the target shape is a flat shape, and
the controller makes the ratio different among the plurality of regions so that a difference in surface height of the cured film formed on the substrate by performing the process between the plurality of regions falls within an allowable range.

6. The apparatus according to claim 1, wherein the process includes a first curing process of curing the composition by applying first energy to the composition on the substrate, and a second curing process of further curing the composition by applying second energy to the composition on the substrate after the first curing process.

7. The apparatus according to claim 6, wherein the first energy is light and the second energy is heat.

8. The apparatus according to claim 1, wherein the process includes curing the composition in a state in which a mold and the composition on the substrate are in contact with each other.

9. The apparatus according to claim 8, wherein the mold includes a flat surface that contacts the composition on the substrate.

10. The apparatus according to claim 1, wherein the controller determines the ratio of the plurality of kinds of compositions supplied onto the substrate by the supplier in the process, based on information representing a measurement result of a film thickness of a cured film formed by a process in the past.

11. The apparatus according to claim 1, wherein the controller determines the ratio of the plurality of kinds of compositions supplied onto the substrate by the supplier in the process, based on information representing a characteristic of a lithography apparatus configured to form a pattern on the substrate after forming the cured film on the substrate by performing the process.

12. The apparatus according to claim 1, wherein
each of the plurality of kinds of compositions contains a monomer and a polymerization initiator, and
in the plurality of kinds of compositions, the monomers are of the same kind and composition ratios of the polymerization initiators are different.

13. The apparatus according to claim 1, wherein
each of the plurality of kinds of compositions contains a monomer, a polymerization initiator, and a solvating medium, and
in the plurality of kinds of compositions, the monomers and the polymerization initiators are of the same kinds and composition ratios of the solvating media are different.

14. A film forming method of forming a cured film of a composition on a substrate, comprising:
supplying each of a plurality of kinds of compositions having different curing shrinkage rates onto the substrate; and
curing the composition supplied onto the substrate in the supplying,
wherein the substrate includes a plurality of regions with different average surface heights per unit area, and
wherein in the supplying, a ratio of the plurality of kinds of compositions supplied onto the substrate is made different among the plurality of regions so that a surface shape of the cured film formed on the substrate by performing the curing is a target shape.

15. An article manufacturing method, comprising:
forming a cured film of a composition on a substrate using a film forming method defined in claim 14;
processing the substrate having undergone the forming; and
manufacturing an article from the substrate having undergone the processing.
